(19) United States
(12) Patent Application Publication
(10) Pub. No.: US 2025/0135568 A1
(43) Pub. Date: May 1, 2025

(54) DEVICE FOR TRANSFERRING AND METHOD

(71) Applicant: ams-OSRAM International GmbH, Regensburg (DE)

(72) Inventors: Thomas Schwarz, Regensburg (DE); Markus Boss, Regensburg (DE); Sebastian Wittmann, Regenstauf (DE); Tobias Berthold, Wenzenbach (DE)

(21) Appl. No.: 18/834,551

(22) PCT Filed: Feb. 1, 2023
(86) PCT No.: PCT/EP2023/052444

§ 371 Date: Jul. 30, 2024

(30) Foreign Application Priority Data
Feb. 1, 2022 (DE) 10 2022 102 364.8

(51) Int. Cl. B23K 1/005; B23K 26/0622; B23K 26/53; B23K 101/40; H01L 23/00

(52) U.S. Cl. CPC B23K 1/0056; B23K 26/0622; B23K 26/53; H01L 24/81; B23K 2101/40; H01L 2224/81224

(57) ABSTRACT

In an embodiment a device for transferring at least one semiconductor component from a carrier substrate to a target substrate includes at least one lighting device configured to emit a first light pulse onto the semiconductor component to release it from the carrier substrate and to move it towards the target substrate, the semiconductor component comprising at least one contact surface, which corresponds to at least one contact surface on the target substrate and at least one of the contact surfaces comprising a solder material and to emit a second light pulse after the first light pulse, the second light pulse configured to melt the solder material on the at least one of the contact surfaces before the semiconductor component reaches the target substrate.

### CROSS-REFERENCE TO RELATED APPLICATIONS

This patent application is a national phase filing under section 371 of PCT/EP2023/052444, filed Feb. 1, 2023, which claims the priority of German patent application 10 2022 102 364.8, filed Feb. 1, 2022, each of which is incorporated herein by reference in its entirety.

### TECHNICAL FIELD

The present invention relates to a device for transferring at least one semiconductor component and a method for transferring at least one device.

### BACKGROUND

Semiconductor components, including so-called μLEDs, must be transferred from a carrier or source substrate to a target substrate. The term “target substrate” can be understood to mean another temporary carrier, but also a circuit board, PCB, backplane or similar. It is advisable to use a process that can transfer a large number of devices in a very short time.

This type of transfer is particularly difficult for small devices, the μLEDs mentioned above, as their lateral dimensions are only in the range of a few μm.

When devices are transferred using a so-called laser lift-off process, devices are detached from the carrier substrate by a laser pulse and then transferred to the target substrate. In a second step, the device is then attached to the target substrate. In conventional transfer processes, an electrically insulating catch layer (silicone, liquid epoxy) is required for this purpose in order to bond the chips to the target substrate. This makes electrical connection technology on the target substrate difficult. The use of solder pastes with flux as a catch layer is conceivable but can only be structured with great effort. There is also a risk that high laser energy will damage the semiconductor component.

### SUMMARY

Embodiments provide transfer processes that are suitable for mass transfer on the one hand and that are suitable to reduce an incorrect setting of semiconductor components on the other hand.

The inventors propose a bundle of suitable measures for the transfer in order to make such a transfer safe. An essential aspect here is to provide a solder between the contact surfaces of the semiconductor component and the target substrate for adhesion of the semiconductor component to the target substrate, which is melted with a second laser pulse shortly before the semiconductor component strikes the target substrate. In other words, the solder is melted during the flight of the semiconductor component.

As a result, liquid solder wets both the target substrate and the semiconductor component so that it does not bounce away on impact.

In one aspect of the invention, a device for transferring at least one semiconductor component, in particular an optoelectronic device, from a carrier substrate to a target substrate is provided. Both the semiconductor component and the target substrate each comprise at least one contact surface which correspond to one another, at least one of the contact surfaces comprising a solder material. The device comprises at least one laser device configured to emit a first light pulse onto the semiconductor component for detachment from the carrier substrate towards the target substrate. The device is also configured to emit a second light pulse after the first light pulse. The second light pulse is configured to melt the solder material on the at least one contact surface during the flight of the semiconductor substrate, i.e. before the semiconductor component reaches the target substrate.

This melting process results in mechanical fixing when the semiconductor component hits the surface. This avoids the bouncing that occurs with conventional processes. In this way, a connection is created that is characterized by high shear strength and good electrical and thermal conductivity due to the melted solder. Due to the short melting times of the solder, the risk of oxidation is reduced and yet a good wetting and solder joint is achieved.

The term light pulse is understood to mean a beam of light, in particular generated by a laser. The terms laser pulse or light pulse are therefore understood synonymously for the purposes of this application. However, it should be mentioned that the energy required for detachment and/or melting can also be supplied by other means, in particular by a radio pulse, IR pulse, xenon pulse lamp and the like. This type of energy supply should also fall under the term light pulse.

In one aspect, a distance between the first light pulse and the second light pulse is greater than a pulse duration of at least one of the first and second light pulses, in particular longer than ten times the pulse duration of at least one of the first and second light pulses. This allows the melting time to be easily controlled and set so that it is shortly before the impact time of the semiconductor component. The short time reduces the thermal load on the device, as it hits the carrier immediately after melting and the amount of energy introduced is dissipated again. The electrical, mechanical and thermal interconnect is formed after the solder has solidified.

In some aspects, it has proved expedient to set an energy or a power of the second light pulse greater than an energy or a power of the first light pulse. The energy introduced is preferably set such that it is sufficient to melt the solder. In some aspects, however, it is provided that the second light pulse directly follows the first light pulse and in particular comprises the same energy or the same power. This may also allow a particularly simple realization with only one laser.

In this context, in some aspects, the device comprises a beam splitter which is designed to generate the first and second light pulses. The second light pulse can be delayed (e.g. by a longer path). It is also possible to split the energy of a light pulse using the beam splitter so that the two resulting light pulses comprise different energies. Alternatively, 2 light pulses can also be combined using a beam splitter.

In this embodiment, the first and second light pulses can comprise essentially the same wavelength. In some aspects, however, light pulses with different wavelengths can also be used for this purpose. Thus, in some embodiments, it is provided that the first light pulse comprises a significantly shorter wavelength than the second light pulse. The first light pulse can comprise a wavelength in the ultraviolet or blue spectrum, while the second light pulse is in the infrared range. In some aspects, the wavelengths of both light pulses, and in particular the second light pulse, are matched to the materials. For example, the second light pulse should have a wavelength that is well absorbed in the solder or the impinging surface in order to enable a high energy input.

Some other aspects deal with the orientation and direction of the different light pulses. For example, the at least one laser device may be configured to emit the first laser pulse onto at least one side of the semiconductor component that faces away from the solder material. Put simply, the laser device is designed so that the first light pulse strikes a side of the semiconductor component that is connected to the carrier substrate. This side can comprise a material which is arranged between the carrier substrate and the semiconductor component and which is heated up well by the first light pulse or at least significantly reduces its adhesion, so that the semiconductor component detaches from the carrier substrate.

For this purpose, a material can be provided which vaporizes during the first laser pulse. In some aspects, the semiconductor component is attached to the carrier substrate via a retaining layer that can be detached by the first light pulse. Alternatively or additionally, the side of the semiconductor component on which the first light pulse occurs may comprise a roughening or a structuring.

Further aspects deal with the position of the solder material and, as a result, the configuration of the second light pulse for melting the solder. In some aspects, the solder is provided on a contact surface of the semiconductor component. Accordingly, in this embodiment, the laser device for emitting the second light pulse is configured such that the second light pulse impinges on the solder material on the contact surface of the semiconductor component or the target substrate. In some aspects, the laser device is configured to emit the second light pulse such that it strikes the contact surface of the semiconductor component covered with solder material. The second light pulse can thus be opposite to the direction of fall of the semiconductor component or at least run at an angle, in particular less than 45°. The advantage of shining the second light pulse directly onto the solder-covered contact surface is that the solder is directly energized. Heat conduction through the semiconductor component is therefore not necessary and the thermal load on the device is reduced.

In another aspect, the solder to be melted is located on a contact surface of the target substrate. This is advantageous because the thermal load on the semiconductor component is further reduced and the melting process can be designed flexibly. A higher energy input is also initially less problematic than for the semiconductor component. In this aspect, the laser device is thus designed to emit the second light pulse onto a contact surface covered with solder material on the target substrate. In some aspects, the contact surface of the semiconductor component also comprises a thin layer of solder. This can serve as a buffer layer that absorbs some of the thermal energy when the device encounters the molten solder.

In some aspects, the second light pulse can therefore hit the contact surface covered with solder material vertically, but also at an angle.

A further aspect relates to a method for transferring a semiconductor component, in particular an optoelectronic device, from a carrier substrate to a target substrate, wherein the semiconductor component comprises at least one contact surface corresponding to at least one contact surface on the target substrate, at least one of the contact surfaces comprising a solder material. In the method, a first light pulse is generated and emitted onto the semiconductor component to detach the conductive substrate from the carrier substrate. After detachment, the semiconductor substrate falls towards the target substrate. A second light pulse is then generated after the first light pulse, which is configured to melt the solder material on the at least one contact surface during the flight of the semiconductor component.

In some aspects, the second light pulse occurs later than the first light pulse, so that both light pulses are also separated in time. By selecting the timing of the second light pulse, as well as its energy, it can be ensured that the solder material is melted shortly before the semiconductor component hits the contact surface of the target substrate, so that the device adheres to it.

In some aspects, it is useful to have the first light pulse impinge on the semiconductor component on a side facing away from the solder material. In some aspects, it may be provided that the first light pulse radiates through the carrier substrate, i.e. falls on the semiconductor component from “behind”. In some aspects, this can result in vaporization or dissolution of an adhesive layer between the semiconductor component and the carrier substrate.

In some other aspects, it may again be provided that the second light beam advantageously falls directly onto the contact surface covered with solder material. Irradiation of the second light pulse can thus take place from “the front”. Thus, in some aspects, the step of generating the second light pulse comprises emitting the second light pulse onto solder material arranged on a contact surface of the semiconductor component opposite to the side.

Alternatively, the second light pulse can also be emitted onto solder material and melt it, which is located on a contact surface of the target substrate. This light pulse can also be emitted either from above or from an angle onto the contact surface, but also from below, i.e. through the target substrate. This variant has the advantage that thermal stress on the semiconductor component caused by the second light pulse is avoided.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a version of a conventional process for transferring semiconductor components;

FIG. 2 shows a first step of a method for transferring a semiconductor component according to the proposed principle;

FIG. 3 shows a second step of a method for transferring a semiconductor component according to the proposed principle;

FIG. 4 shows various designs of semiconductor components suitable for the proposed method;

FIG. 5 shows the second step of another embodiment of the method for transferring a semiconductor component with some aspects of the proposed principle;

FIG. 6 shows the second step of a third embodiment of the method for transferring a semiconductor component according to some aspects of the proposed principle;

FIG. 7 illustrates the second step of a fourth embodiment of the method for transferring a semiconductor component according to some aspects of the proposed principle;

FIG. 8 is another example of the second step of one of the methods for transferring a semiconductor component according to some aspects of the proposed principle;

FIG. 9 shows a schematic structure of a device for transferring semiconductor components according to some aspects of the proposed principle;

FIG. 10 shows a diagram with some characteristic parameters over time for a method of transferring semiconductor components according to some aspects of the proposed principle;

FIG. 11 shows a second diagram with some characteristic parameters over time for a method of transferring semiconductor components according to some aspects of the proposed principle; and

FIG. 12 is another diagram showing some characteristic parameters over time for a method of transferring semiconductor components according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

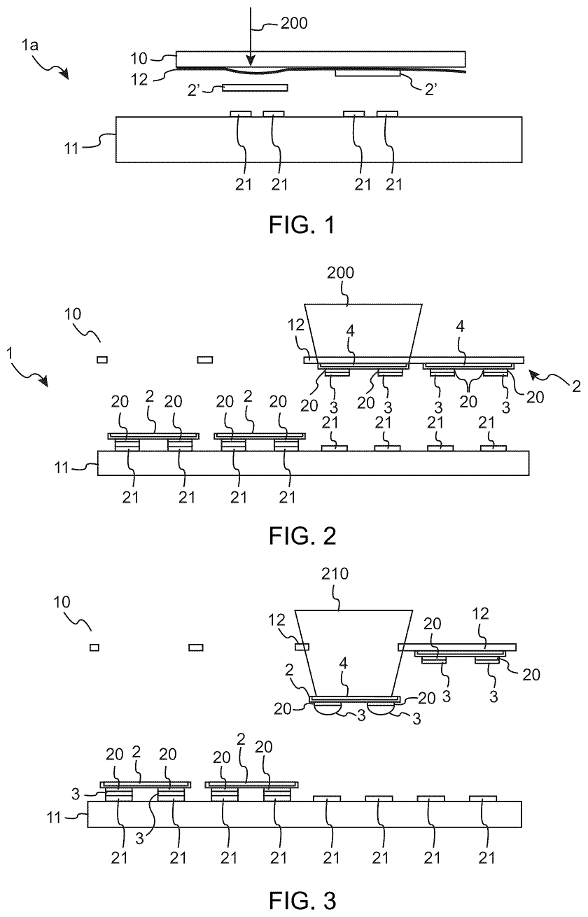

FIG. 1 shows the schematic structure of a device 1A for transferring semiconductor components from a carrier substrate to a target substrate. The semiconductor components 2′ are attached to a carrier substrate 10 by means of an adhesive or other adhesive layer 12. A laser device, not shown here, emits a first light pulse 200 which passes through the transparent carrier substrate 10 and causes a change in the adhesive layer 12. For example, such a change can be a bulging, a melting or even an evaporation of material in the adhesive layer 12, so that the semiconductor component 2′ connected to the adhesive layer 12 is detached and accelerated towards the target substrate 11.

The target substrate 11 again comprises one or more contact surfaces 21 facing the device 2′. Such processes are generally known, whereby the biggest problem here is the adhesion of the device 2′ to the target substrate with the elements 21 located on it. The elements 21 can, for example, be coated with solder pastes or the like, so that they in turn act as an adhesive layer and prevent the semiconductor component falling on them from jumping off or bouncing off. Alternatively, electrically insulating adhesive layers made of silicone or liquid or hardened epoxy, for example, would also be conceivable here. However, all these solutions have in common that further measures and steps are necessary in order to achieve an adhesion-stable and possibly also electrically conductive connection between the semiconductor component 2′ and the target substrate 11. This is particularly useful if the target substrate 11 is not in itself a temporary carrier, but contains, for example, a backplane, a PCB or another structure already containing electronic circuitry. In such a case, it is advantageous to already place the semiconductor component on contact surfaces provided for this purpose in order to subsequently attach it there.

To this end, the inventors propose a method for transferring semiconductor components from a carrier substrate to a target substrate, the essential steps of which are shown in FIGS. 2 and 3.

FIG. 2 shows the state of the transfer process after some semiconductor components of a large number of devices have already been successfully transferred. The individual devices 2 comprise a semiconductor body 4 and at least two contact surfaces 20 on a surface opposite the target substrate 11. Furthermore, a solder material 3 is applied to each of the contact surfaces 20 of the devices 2. The contact surfaces 20 of the devices 2 correspond to contact surfaces 21 on a target substrate 11, i.e. they have the same distance and the same relative position to each other. The semiconductor components 2 are attached to a transparent carrier substrate 10 via an adhesive layer 12.

For a transfer to the target substrate, a first laser light pulse 200 is now irradiated through the transparent carrier substrate 10 onto the rear side of the semiconductor components 2 in a first step. The energy introduced in this process is partially reflected and absorbed in the adhesive layer 12, causing it to heat up and possibly partially vaporize or become liquid in the interface between the semiconductor component 2 and the carrier substrate 10. In any case, the energy introduced reduces the adhesive force between the adhesive layer 12 and the semiconductor component in such a way that the latter detaches from the carrier substrate and the adhesive layer 12 and falls towards the target substrate 11.

The flight time of the semiconductor component essentially results from the distance between the carrier substrate 10 and the target substrate 11 and is in the range of many nanoseconds to a few microseconds. This results from the fact that the detachment process gives the device an initial impulse due to the explosive vaporization of the adhesive layer, so that its initial speed is significantly higher. In this context, it is advisable to bring the carrier substrate 10 and the target substrate 11 as close together as possible in order to minimize possible lateral variations during flight. These can be caused by non-perpendicular forces when the semiconductor component 2 is detached from the adhesive layer 12, whereby a velocity vector is imparted to the semiconductor component 2 not only vertically downwards, but also in a lateral direction. In order to minimize the effects in this respect, it is therefore advisable to align the carrier substrate 10 and the target substrate 11 as closely and closely as possible to each other.

FIG. 3 now shows the next step in the process for transferring semiconductor components according to the proposed principle.

During the fall time of the semiconductor component 2 in the direction of the target substrate 11 and the contact surfaces 21 corresponding to the contact surfaces 20, a second laser light pulse 210 is emitted onto the semiconductor component 2 at the rear. This is higher in energy than the first laser light pulse 200. Alternatively, it can also last longer and/or have a shorter wavelength and thus higher-energy radiation. In any case, the energy introduced by the second laser light pulse 210 is sufficient to melt and at least partially liquefy the solder material 3 located on the surface of the contact surfaces 20.

The melting process takes place during the flight phase, i.e. before the semiconductor component reaches the contact surfaces 21 on the target substrate 11. The molten solder now adheres directly to the contact surfaces 21 when the semiconductor component 2 hits the target substrate 11. The laser light pulse 210 is already deactivated at this point, so that the molten solder material 3 adheres to the contact surfaces 21 and solidifies there.

In this way, not only is a mechanical connection created between the semiconductor component 2 and the target substrate 11, but also an electrical connection at the same time. Due to the large heat capacity of the contact surfaces 21 and the target substrate 11 itself, the energy present in the molten solder material and the heat present in the semiconductor component is quickly dissipated, so that the solder material 3 solidifies almost immediately when the semiconductor component 2 hits the contact surfaces 21, thus ensuring a mechanical connection. The results of such a transfer are shown in the other devices in the left part of FIGS. 2 and 3. The solder material 3 is located between the two contact surfaces 20 and 21.

The laser energy required to melt the solder material can be estimated from the heat capacity of the semiconductor component and the solder material. One possible solder material is tin, for example, which is deposited on the contact surface 20 before the transfer process. With a possible contact area of 50×50 μm and a thickness of the solder contact layer of 3 μm, this results in a total volume in the range of 7500 μm³. With a tin density of 6.5 g/cm³, this results in a mass of around 4.9 nanograms. This mass must now be heated by the energy of the laser steel and then melted. The melting point of tin is approximately 232° C., resulting in a difference of approximately 210K. With a specific heat capacity of 222 J/kg/K, the energy required to bring the tin on the contact surface to the melting temperature is around 2.2 μJ. Added to this is the melting energy of about 3 μJ, which results from the specific heat of fusion of about 7 kJ/mol mol.

In contrast, the typical laser energy required to detach the semiconductor component from the carrier substrate is around 2 μJ. This means that approximately three times the amount of energy is required for the actual melting process. There is also an additional energy contribution, as part of the applied laser energy also heats the semiconductor component.

The devices used for the laser light, for example excimer lasers, have the necessary energy to detach the semiconductor laser from the carrier substrate by means of very short pulses in the picosecond range and to melt the solder material during the flight.

It is possible to use a laser device for both irradiation processes and to divide the light pulse emitted by the laser device accordingly. For example, part of the light pulse is decoupled and used to detach the semiconductor component from the carrier substrate. The second, larger part is delayed in time, for example by an additional travel distance, and then beamed back onto the semiconductor body during the flight phase. At a distance between the carrier substrate and the target substrate of about 50 μm, the flight time of the semiconductor component is in the range of 3 ms due to the acceleration due to gravity of 9.81 m/s² and free fall in a vacuum, without taking the above-mentioned initial impulse into account. In practice, the flight time due to an initial impulse is in the range of μ seconds or even less. It is therefore possible to use both a single laser and two different lasers for the two process steps.

FIG. 9 shows an embodiment example in which two laser devices 20 and 21 are equipped for generating and emitting the first light pulse 200 and the second light pulse 210, respectively. The two laser devices emit their respective light pulses to a beam splitter 220, which is designed to be partially transparent. The first light pulse 200 is redirected by the beam splitter 220 and serves to detach the semiconductor component from the carrier substrate 10. A second light pulse 210 is generated with a time delay by the second laser device 21, which melts the solder material on the contact surfaces of the semiconductor body during the flight before it reaches the corresponding contact surfaces on the target substrate 11. The two laser devices 20 and 21 are designed to generate laser pulses of different wavelengths for this purpose. While the device 20 emits a laser pulse 200 in the ultraviolet or blue part of the spectrum, the device 210 generates a laser in the infrared range. The wavelengths are matched to the material in which they are to be absorbed. In this respect, various wavelengths are therefore possible and the above-mentioned ranges are to be understood as merely exemplary.

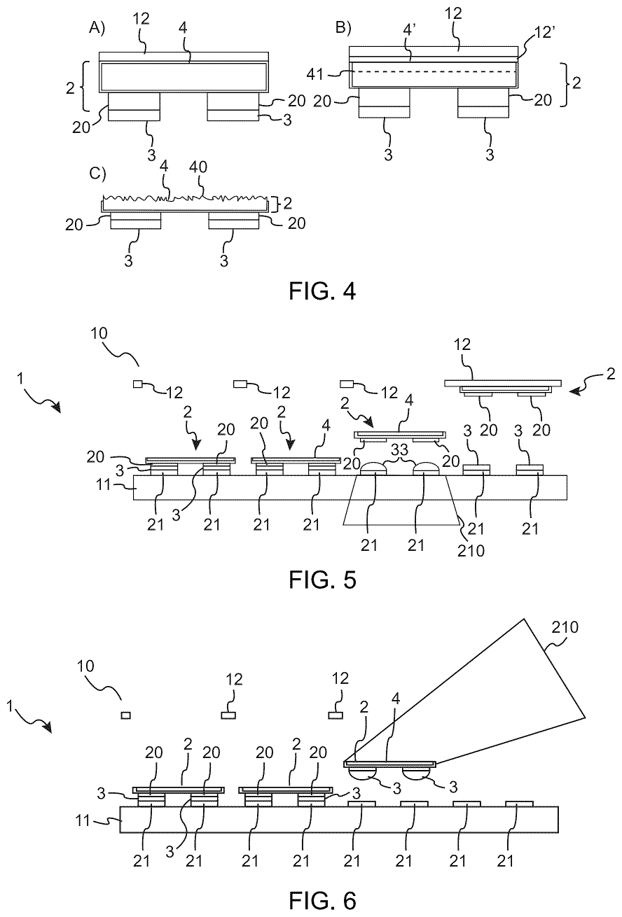

In this respect, FIG. 4 shows various semiconductor components that are suitable for such a transfer process. Sub-FIG. 4A shows a device comprising a semiconductor body 4, on the surface of which several contact surfaces 20 are arranged. A solder material 3, for example made of tin, is applied to the contact surfaces 20. The semiconductor component 2 is attached to the adhesive layer 12 on the rear side opposite the contact surfaces 20.

FIG. 4B shows a further example of a semiconductor component 2, this time in the form of an optoelectronic device. This comprises a semiconductor body 4′ with an active zone 41. The optoelectronic device is attached to the adhesive layer 12 via an adhesive layer 12′. When detached by a laser light pulse, this additional adhesive layer 12′ is vaporized. The gas generated detaches the semiconductor component from the adhesive layer 12.

Finally, sub-FIG. 4C shows a further embodiment of a semiconductor component 2 in which the surface 40 of the device facing away from the contact surfaces 20 is roughened. The roughening causes an improved energy transfer when the device is detached, so that it is easier to detach from the adhesive layer and the melting process for the solder material 3 is accelerated.

In addition to the possibility of irradiating the second laser light pulse directly onto the device, there are several alternatives in which the second light pulse is emitted onto the semiconductor component along a different direction. In addition, it is possible to apply the solder material 3 not to the contact surfaces of the semiconductor component, but to the contact surfaces 21 of the target substrate 11 and to melt it there. This has the advantage that the additional energy input into the semiconductor component required for melting is avoided, so that it does not experience any major thermal stress. In addition, the melting process can be controlled completely independently of the first light pulse and thus of the detachment process.

FIG. 5 shows such an embodiment example. In this example, after the semiconductor component 2 has been detached from the adhesive layer 12, a second light pulse is generated shortly before it hits the target substrate 11 and directed onto the contact surfaces 21 of the target substrate. The contact surfaces 21 of the target substrate 11 are covered with a solder material 3, which is melted by the second laser pulse. For this purpose, the second laser light pulse is emitted from below through the target substrate onto the contact surfaces 21 as shown in FIG. 5. The target substrate 11 is transparent for the light wavelength of the second light pulse. This embodiment has the advantage that the laser beam is not obscured or shadowed by the falling semiconductor component. In this way, reflection from the solder material onto the falling device is also avoided or at least reduced. Alternatively, however, it is also possible to irradiate the second laser light pulse 210 from above or sideways onto the contact surfaces 21 in order to melt the solder material 3 present there. The melting process is completed when the semiconductor component 2 strikes the contact surfaces 21.

FIG. 6 shows a further alternative embodiment in which the laser beam 210 is not irradiated through the output substrate 10, but rather sideways onto the falling semiconductor component 2. In the embodiment example, the irradiation in this form takes place from the side, so that both the semiconductor body 4 of the semiconductor component 2 and the solder material 3 are uniformly illuminated and heated by the laser beam. In a further embodiment, the second light pulse 210 is directed from below, i.e. from the side of the target substrate 11, onto the contact surfaces 20 of the falling device 2 and melts the existing solder material 3 there. Like the embodiment in FIG. 5, this embodiment provides the advantage that less energy input is required for melting and thus the thermal load on the semiconductor component is reduced.

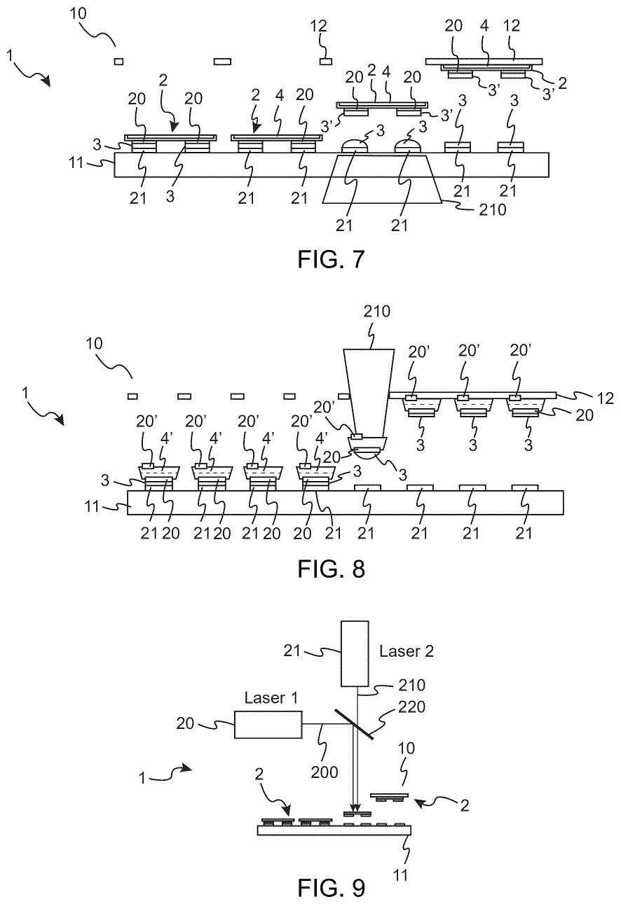

FIG. 7 shows a further embodiment in which a solder material 3 is applied to the contact surfaces 21 of the target substrate and a solder material 3′ is applied to the contact surfaces of the semiconductor component 2. The solder material 3′ serves as an additional heat buffer. It ensures that the device generally does not become warmer than the melting temperature of the solder material (this property is also present in the other embodiments), as the additional energy introduced serves to generate the necessary melting energy without further increasing the temperature. By adapting the solder, a thermally sensitive semiconductor component can thus be protected.

In the embodiment example presented here, the second laser light pulse 210 is irradiated onto the solder material 3 on the contact surfaces 21 of the target substrate 11 and melts the solder material there. When the semiconductor body 2 strikes the contact surfaces 21 with the melted solder 3, it now bonds with the solder material 3′ on the contact surfaces 20 and heat is transferred. Depending on the amount of energy introduced into the material 3, this heat transfer is at least partially sufficient to melt the solder material 3′ at least on the surface or to soften it so that it bonds well with the cooling solder material 3. In any case, the solder material 3′ also acts as an additional heat sink on the contact surfaces 20 and reduces the thermal load on the semiconductor body 2.

In a further embodiment, it is also conceivable to melt both the solder material 3 on the target substrate and the solder material 3′ on the semiconductor component. This can be done by a common light pulse that hits both solder materials, e.g. shortly before impact, or also by a further third light pulse.

In addition to the transfer of semiconductor components and also horizontal optoelectronic devices in the previous figures, vertical optoelectronic devices can also be transferred using the proposed principle.

FIG. 8 shows an embodiment example for the transfer of optoelectronic devices. The optoelectronic devices comprise a first contact area 20 on a first side and a second contact area 20′ on an opposite second side. They are thus designed as vertical light-emitting diodes or vertical μLEDs. A thin layer of solder material 3 is applied to the contact surface of the devices on the side facing the target substrate. During the transfer process, after a first light pulse to detach the devices from the adhesive layer 12 of the carrier substrate 10, a second light pulse is emitted onto the device in the final flight phase. This melts the solder on the contact surface 20 so that it bonds mechanically and thermally with the corresponding contact surfaces 21 on the target substrate on impact. Here too, the melting process is essentially complete before the device hits the substrate.

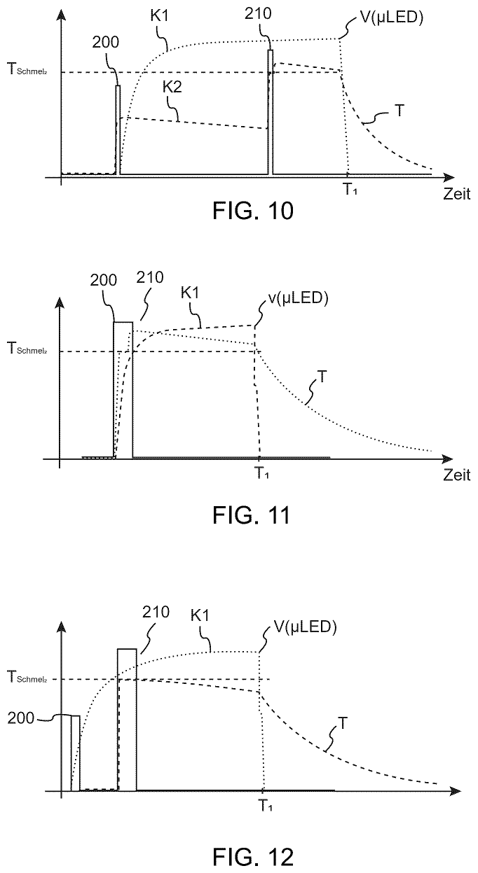

FIGS. 10, 11 and 12 now show various time, energy and temperature diagrams that illustrate the different flight phases of the semiconductor components during the transfer process on the one hand and the corresponding temperatures and light pulses on the other.

In FIG. 10, two spaced-apart short light pulses 200 and 210 are generated in the picosecond range. The first light pulse 200 is used to detach the semiconductor component from the carrier substrate, which is shown in the curve K1 moving towards the target substrate at an accelerated speed. In the process, the semiconductor component can be given an additional impulse, for example by vaporized material of the carrier substrate or an adhesive layer, so that the device comprises a higher initial speed.

At the same time, curve K2 shows the temperature curve across the device. As can be seen, the first light pulse generates a temperature increase in the device, but is still below the melting temperature of the solder applied to the contact surfaces.

During the flight phase, particularly towards the end of the flight phase, a second light pulse 210 is generated and irradiated onto the contact surfaces of the semiconductor component. This second light pulse comprises a higher energy than the first light pulse and thus causes a steep rise in the temperature of the solder material above the melting temperature Tₘₑₗₜ. The solder applied to the contact surfaces of the semiconductor body is thus melted and then begins to decrease slightly in temperature due to heat loss (e.g. radiation or heat conduction) for the remainder of the flight phase. At time T1, the device hits the contact surfaces 21 on the target substrate and the solder comes into contact with the corresponding contact surfaces. Due to the significantly lower temperature and the high heat capacity of these additional contact surfaces 21, the solder solidifies and connects the two contact surfaces 20 and 21 mechanically and electrically.

The intervals between the first and second laser light pulses can be adjusted as required. However, the second light pulse should be completed before impact so that the solder has melted (this aspect is independent of whether the solder is applied to the contact surfaces 20 or 21). Otherwise, there is a risk of bouncing-off, i.e. the lateral position or even the inclination of the device may change significantly, thus impairing the electrical function.

Alternatively, a significantly simplified embodiment can also be used, in which the first light pulse 200 and the second light pulse 210 for melting the solder material immediately follow one another.

FIG. 11 shows an example of such an embodiment. In this example, the first light pulse is used to detach the semiconductor component, which then moves in free fall along the curve K1 towards the target substrate. At time T1 it has reached the target substrate. After the first light pulse, a second light pulse 210 is generated immediately, which brings the temperature of the slot on the contact surfaces above the melting temperature and thus causes the slot to melt. As shown, this second light pulse can have the same energy as the first light pulse, but its energy can also be higher or lower. It is essential that the power of the second light pulse is selected so that the solder material melts essentially due to the energy input of the second light pulse and not the first light pulse.

During the flight phase, the temperature of the molten solder decreases until the device reaches the second contact surfaces on the target substrate. Due to the connection between the contact surfaces by means of the solder material, the heat present in the solder material is quickly dissipated, the solder solidifies and the temperature decreases exponentially.

Finally, FIG. 12 shows the temperature diagram for an embodiment in which the solder material is applied to the contact surfaces of the target substrate and also to the contact surfaces of the device as a heat buffer. In this case, the temperature curve Tis the temperature of the device. With the first light pulse 200, the device is detached and begins to fall towards the contact surface. The second light pulse melts the solder on the contact side and also heats the solder on the contact surfaces of the semiconductor component. Due to the heat buffer, however, the temperature of the device does not rise above the melting temperature, so that the device is protected. In this embodiment example, the melting temperature then drops slightly until the device hits the contact surfaces at time T1. From this point onwards, the temperature drops again and the two solder surfaces harden together. Due to the additional solder material 3′ on the contact surfaces 20 of the semiconductor component, the temperature of the device does not rise above the melting temperature, but remains slightly below it. This has the advantage that the thermal load on the device itself is reduced.

1-16. (canceled)

17. A device for transferring at least one semiconductor component from a carrier substrate to a target substrate, the device comprising:
at least one lighting device configured to:
emit a first light pulse onto the semiconductor component to release it from the carrier substrate and to move it towards the target substrate, the semiconductor component comprising at least one contact surface, which corresponds to at least one contact surface on the target substrate and at least one of the contact surfaces comprising a solder material; and
emit a second light pulse after the first light pulse, the second light pulse configured to melt the solder material on the at least one of the contact surfaces before the semiconductor component reaches the target substrate.

18. The device according to claim 17, wherein the lighting device is configured so that a distance between the first light pulse and the second light pulse is greater than a pulse duration of at least one of the first and second light pulses.

19. The device according to claim 17, wherein the lighting device is configured so that an energy or a power of the second light pulse is greater than an energy or a power of the first light pulse.

20. The device according to claim 17, wherein the lighting device is configured so that the second light pulse directly follows the first light pulse and comprises the same energy or the same power.

21. The device according to claim 17, wherein the lighting device is configured to emit the first light pulse onto at least one side of the semiconductor component facing away from the solder material.

22. The device according to claim 21, wherein the side of the semiconductor component comprises a roughening or a patterning.

23. The device according to claim 17, wherein the semiconductor component is attached to the carrier substrate via a retaining layer, which is detachable by the first light pulse.

24. The device according to claim 17,
wherein the lighting device is configured to emit the second light pulse onto the at least one contact surface of the semiconductor component covered with the solder material, and/or
wherein the lighting device is configured to emit the second light pulse onto the at least one contact surface of the target substrate covered with the solder material.

25. The device according to claim 24, wherein the at least one contact surface of the semiconductor component is covered with the solder material.

26. The device according to claim 17, wherein the solder material is melted when it reaches the target substrate.

27. A method for transferring a semiconductor component from a carrier substrate to a target substrate, wherein the semiconductor component comprises at least one contact surface, which corresponds to at least one contact surface on the target substrate, at least one of the contact surfaces comprising a solder material, the method comprising:
generating and emitting a first light pulse onto the semiconductor component to release it from the carrier substrate and to move it towards the target substrate; and
generating a second light pulse after the first light pulse, the second light pulse configured to melt the solder material on the at least one of the contact surfaces during a move of the semiconductor component.

28. The method according to claim 27, wherein a time interval between the first light pulse and the second light pulse is greater than a pulse duration of at least one of the first and second light pulses.

29. The method according to claim 27, wherein an energy or a power of the second light pulse is greater than an energy or a power of the first light pulse.

30. The method according to claim 27, wherein the first light pulse impinges on the semiconductor component on a side facing away from the solder material.

31. The method according to claim 27, wherein emitting the first light pulse onto the semiconductor component comprises completely or partially vaporizing or dissolving an adhesive layer between the semiconductor component and the carrier substrate.

32. The method according to claim 27,
wherein generating the second light pulse comprises emitting the second light pulse onto the solder material disposed on a contact surface of the semiconductor component opposite to a side, and/or
wherein generating the second light pulse comprises emitting the second light pulse onto the at least one contact surface of the target substrate covered with at least one solder material.
